(19) United States
(12) Patent Application Publication
(10) Pub. No.: US 2024/0012976 A1
(43) Pub. Date: Jan. 11, 2024

(54) METHOD OF MONITORING A SIGNAL IN A CIRCUIT SIMULATION

(71) Applicant: Renesas Design (UK) Limited, Bourne End (GB)

(72) Inventor: Peter GROVE, Newtongrange (GB)

(73) Assignee: Renesas Design (UK) Limited, Bourne End (GB)

(21) Appl. No.: 18/183,561

(22) Filed: Mar. 14, 2023

Related U.S. Application Data
(60) Provisional application No. 63/358,652, filed on Jul. 6, 2022.

(51) Int. Cl. G06F 30/38

(52) U.S. Cl. CPC G06F 30/38

(57) ABSTRACT

A computer-implemented method of monitoring a first signal with respect to a plurality of threshold values within a simulation of an electronic circuit, the method comprising providing a first threshold value, monitoring the first signal with respect to the first threshold value, detecting that the first signal has reached or has traversed across the first threshold value, and generating a second threshold value in response to the detection of the first signal having reached or having traversed across the first threshold value.

### CROSS-REFERENCE TO RELATED APPLICATION

The subject application claims the benefit of provisional U.S. Patent Application No. 63/358,652, filed on Jul. 26, 2022. The entire disclosure of U.S. Patent Application No. 63/358,652 is incorporated herein by this reference.

### BACKGROUND

The present disclosure relates to a computer-implemented method of monitoring a signal within a simulation of an electronic circuit. In particular, the present disclosure related to a method of monitoring the signal with respect to threshold values within a simulation of an electronic circuit.

A simulation of an electronic circuit may be run using a model or a stimulus/monitor component that triggers a discrete event when a threshold is crossed by a signal.

For example, within an analog simulation, signals may be defined as being “continuous” rather than “discrete”, such that the model or the stimulus/monitor component triggers the event when a threshold is crossed by the “continuous” signal.

Simulation software packages may include different methods of detecting that a threshold has been crossed by a signal. For example, Verilog-AMS includes threshold statements, such as “above” and “cross” statements, for this function.

Specifically, “above” and “cross” statements within Verilog-AMS act to control the simulator to ensure that there is an analog matrix solution around the threshold for accuracy, and an “if-else” construct may be applied if the nearest analog matrix solution is good enough for a given simulation. Use of the Verilog-AMS “above” statement is typically preferable than use of the “cross” statement. The “above” statement is unidirectional, whereas the “cross” statement is bidirectional. For a bidirectional “cross” statement two “above” statements are needed (one to detect rising signals and one to detect falling signals). Additionally, “if-else” statements provide limited accuracy when compared with “above” statements.

If a user wants to have three rising thresholds, then three thresholds statement are needed. If this is both for a rising and falling, then the number can double. Expanding this to N thresholds (where N is an integer greater than or equal to one) means that 2N statements are needed.

It will be appreciated that the more threshold statements that are required, the greater the number of computations that are required by the computer running the simulation software.

### SUMMARY

It is an object of the present disclosure to provide a method of monitoring a signal within a computer-based simulation of an electronic circuit that is more efficient than known methods.

Furthermore, it is an object of the present disclosure to provide a method of monitoring a signal with respect to thresholds, within a simulation of an electronic circuit, that is more efficient than known methods.

According to a first aspect of the disclosure there is provided a computer-implemented method of monitoring a first signal with respect to a plurality of threshold values within a simulation of an electronic circuit, the method comprising providing a first threshold value, monitoring the first signal with respect to the first threshold value, detecting that the first signal has reached or has traversed across the first threshold value, and generating a second threshold value in response to the detection of the first signal having reached or having traversed across the first threshold value.

Optionally, the first signal comprises an analog signal or a digital signal.

Optionally, the simulation of the electronic circuit is undertaken using a hardware description language.

Optionally, the hardware description language is SystemVerilog.

Optionally, the hardware description language is Verilog-AMS.

Optionally, the method comprises stopping the monitoring of the first signal with respect to the first threshold value after detecting that the first signal has reached or has traversed across the first threshold value.

Optionally, detecting that the first signal has traversed across the first threshold value comprises detecting that the first signal has risen above the first threshold value, or detecting that the first signal has fallen below the first threshold value.

Optionally, generating a second threshold value in response to the detection of the first signal having traversed across the first threshold value comprises generating a second threshold value in response to the detection of the first signal having risen above the first threshold value, or generating a second threshold value in response to the detection of the first signal having fallen below the first threshold value.

Optionally, generating a second threshold value comprises accessing a memory element that is configured to store one or more stored threshold values, extracting a stored threshold value from the memory element, and setting the extracted stored threshold value as the second threshold value.

Optionally, the method comprises storing one or more stored threshold values within the memory element during the running of the simulation and prior to the generation of the second threshold value.

Optionally, the method comprises monitoring the first signal with respect to the second threshold value.

Optionally, the method comprises detecting that the first signal has reached or has traversed across the second threshold value.

Optionally, the method comprises detecting that the first signal has traversed across the second threshold value comprises detecting that the first signal has risen above the second threshold value, or detecting that the first signal has fallen below the second threshold value.

Optionally, the method comprises generating a third threshold value in response to the detection of the first signal having reached or having traversed across the second threshold value.

Optionally, the method comprises generating a third threshold value in response to the detection of the first signal having traversed across the second threshold value comprises generating a third threshold value in response to the detection of the first signal having risen above the second threshold value, or generating a third threshold value in response to the detection of the first signal having fallen below the second threshold value.

Optionally, the method comprises detecting that the first signal has reached or has traversed across the first threshold value for a second time, and generating a fourth threshold value in response to the detection of the first signal having reached or having traversed across the first threshold value a second time.

Optionally, the method comprises monitoring the first signal with respect to the first threshold value and the second threshold value over a sequence of time steps.

Optionally, the method comprises detecting that the first signal has traversed across the first threshold value comprises detecting that the first signal is within a first bounding box of the first threshold value, the first bounding box being dependent on a first time step, a first time tolerance and a first threshold tolerance.

Optionally, the method comprises detecting that the first signal has traversed across the second threshold value comprises detecting that the first signal is within a second bounding box of the second threshold value, the second bounding box being dependent on a second time step, a second time tolerance and a second threshold tolerance.

According to a second aspect of the disclosure there is provided an electronic circuit simulation tool configured to monitor a first signal with respect to a plurality of threshold values within a simulation performed by the electronic circuit simulation tool, the electronic circuit simulation tool being configured to provide a first threshold value, monitor the first signal with respect to the first threshold value, detect that the first signal has reached or has traversed across the first threshold value, and generate a second threshold value in response to the detection of the first signal having reached or having traversed across the first threshold value.

It will be appreciated that the electronic circuit simulation tool of the second aspect may include providing and/or using features set out in the first aspect and can incorporate other features as described herein.

### BRIEF DESCRIPTION OF THE DRAWINGS

The disclosure is described in further detail below by way of example and with reference to the accompanying drawings in which:

FIG. 1(a) is a flow chart of a computer-implemented method of monitoring a first signal with respect to a plurality of threshold values in accordance with a first embodiment of the present disclosure, FIG. 1(b) is a schematic of a simulation environment;

FIG. 2(a) is a schematic that is illustrative of the existing threshold checking techniques, FIG. 2(b) is a schematic that is illustrative of the threshold checking technique provided by the method of FIG. 1(a);

FIG. 3(a) is a graph showing the application of the method of FIG. 1(a) in accordance with a second embodiment of the present disclosure, FIG. 3(b) is a graph showing the application of the method of FIG. 1(a) in accordance with a third embodiment of the present disclosure, FIG. 3(c) is a graph showing the application of the method of FIG. 1(a) in accordance with a fourth embodiment of the present disclosure, FIG. 3(d) is a graph showing the application of the method of FIG. 1(a) in accordance with a fifth embodiment of the present disclosure;

FIG. 4(a) is a graph showing the application of the method of FIG. 1(a) in accordance with a sixth embodiment of the present disclosure, FIG. 4(b) is a graph showing the application of the method of FIG. 1(a) in accordance with a seventh embodiment of the present disclosure, FIG. 4(c) is a graph showing the application of the method of FIG. 1(a) in accordance with an eighth embodiment of the present disclosure, FIG. 4(d) is a graph showing the application of the method of FIG. 1(a) in accordance with a ninth embodiment of the present disclosure;

FIG. 5 is a schematic of a SystemVerilog Module which instances a Verilog-AMS Module;

FIG. 6 is a graph showing the application of the method of FIG. 1(a) and described in relation to the features of the SystemVerilog Module of FIG. 5;

FIG. 7 is a graph showing the application of the method of FIG. 1(a) and described in relation to the features of the SystemVerilog Module of FIG. 5;

FIG. 8 is a graph showing a specific implementation of an application of the method of FIG. 1(a);

FIG. 9(a) is an illustration of code used in a specific embodiment of the present disclosure, FIG. 9(b) is an illustration of code used in a further specific embodiment of the present disclosure; and

FIG. 10 is a schematic of a computer system which comprises specially modified components for carrying out the methods of the present disclosure.

### DETAILED DESCRIPTION

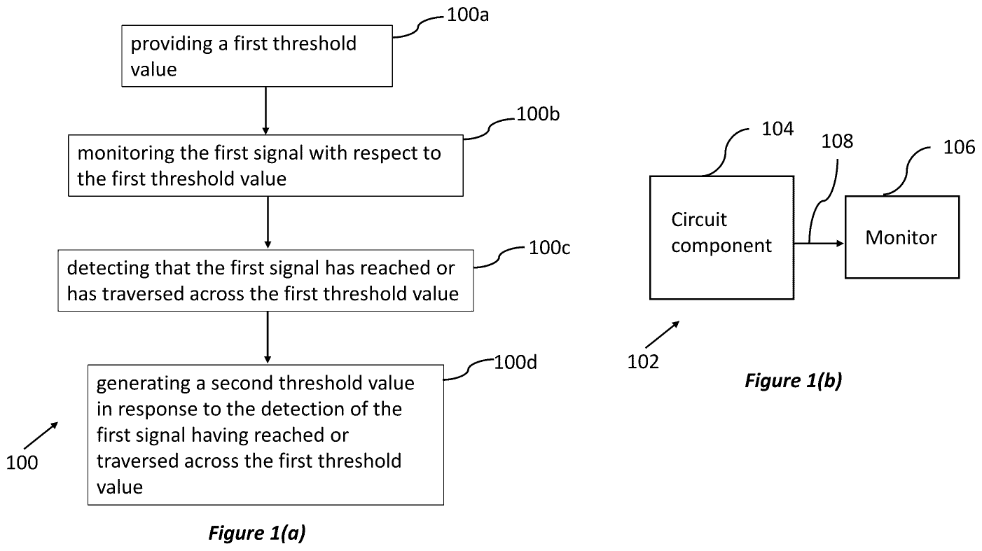

FIG. 1(a) is a flow chart of a computer-implemented method 100 of monitoring a first signal with respect to a plurality of threshold values in accordance with a first embodiment of the present disclosure.

The monitoring of the first signal, as provided by the method 100, is undertaken within a simulation of an electronic circuit.

The method 100 comprises providing a first threshold value, at a step 100a; monitoring the first signal with respect to the first threshold value, at a step 100b; detecting that the first signal has reached or has traversed across the first threshold value, at a step 100c; and generating a second threshold value in response to the detection of the first signal having reached or having traversed across the first threshold value, at a step 100d.

FIG. 1(b) is a schematic of a simulation environment comprising a simulated electronic circuit 102 that comprises a circuit component 104 and a monitor 106. As shown in FIG. 1(b), a signal 108 is provided as an output by the circuit component 104 and is received by the monitor 106, which detects the signal 108 and performs an action in response to a property of the detected signal. It will be appreciated that FIG. 1(b) is provided for illustrative purposes where the signal 108 is an output of the circuit component 104. Alternatively, the signal 108 may be an input to a circuit component, rather than an output. Furthermore, the signal 108 may be provided as an input or an output depending on the context and the operation of the electronic circuit 102. In such circumstances it may be referred to as “a connection” or an “inout” signal.

It will also be appreciated that the signal 108 may simply be any signal 108 within the simulation that is to be monitored, with neither input nor output being appropriate descriptive terms.

FIG. 1(b) is an example of a typical simulation environment which may include monitoring as provided by the method 100. In the present example, the signal 108 corresponds to the first signal, that is monitored by the monitor 106. The monitor 106 of the simulation monitors the first signal 108 with respect to the first threshold value. Once the monitor 108 has detected that the first signal 108 has reached or has traversed across the first threshold value, the second threshold value is generated in response to the event.

The first signal 108 may be, for example, an analog signal or a digital signal. The simulation of the electronic circuit 102 may be undertaken using a hardware description language such as SystemVerilog or Verilog-AMS.

As illustrated by the method 100, the second threshold is only generated after the first threshold has been crossed by the first signal 108. This contrasts with known systems where all thresholds are evaluated concurrently within the simulation. This therefore results in a more efficient method of monitoring a signal with respect to thresholds within a simulation of an electronic circuit.

It will be appreciated that the method 100 and other embodiments described herein, may be applied in the present implementation of Verilog-AMS, but may also be applied to future implementations of Verilog-AMS, for example if future features within the VPI (Verilog Procedural Interface) allows these capabilities.

It will be appreciated that Verilog-AMS may implement the first threshold, the second threshold, and any subsequent threshold using the “cross” and “if-else” statements as well as “above” statements or any future threshold monitoring events that are implemented in future versions of Verilog-AMS, or derivatives of the standard such as SystemVerilog-AMS.

In a specific embodiment, generating the second threshold value may comprises accessing a memory element that is configured to store one or more stored threshold values; extracting a stored threshold value from the memory element; and setting the extracted stored threshold value as the second threshold value.

The method 100 may further comprise storing one or more stored threshold values within the memory element during the running of the simulation and prior to the generation of the second threshold value.

In the present implementation of Verilog-AMS, the number of thresholds statements N are defined before elaboration/compiling as Verilog-AMS. Each threshold statement credentials are checked at each Newton-Raphson iteration to solve the circuit matrix at that timestep to see if it should have triggered. Current practice requires all threshold information to be known before the elaboration time, preventing a dynamic object-oriented approach to be used. Current practice requires the code to be updated when the number of thresholds changes, hampering code reuse and making it difficult to employ methodologies such as UVM. Additionally, the threshold information may be used to guide the next timestep, such that an increased number of thresholds increases the number of CPU cycles.

As the threshold values of a specific embodiment of the present disclosure may be updated during runtime of the simulation, the methods disclosed herein can provide dynamic updating of threshold values, which is not present in known systems. In summary, if an object-oriented approach, such as SystemVerilog/UVM is used, specific embodiments of the methods disclosed herein can enable thresholds to be added and removed dynamically, or can enable the use of multiple processes to control multiple thresholds that are all independent of each other and could have similar thresholds.

Dynamic adding of thresholds may, for example, be provided by the dynamic addition of monitors, such as the monitor 106. Dynamic removal of thresholds may, for example, be provided by the dynamic removal of monitors, such as the monitor 106. In summary, the addition/removal of monitors may be undertaken during the runtime of the simulation.

In summary, the specific embodiments can provide a dynamic number of thresholds without a requirement to change the Verilog-AMS code. Therefore, the present embodiment of the method can provide a way in which a dynamic number of both rising and/or falling thresholds can be utilised without needing upfront knowledge on how many might be required.

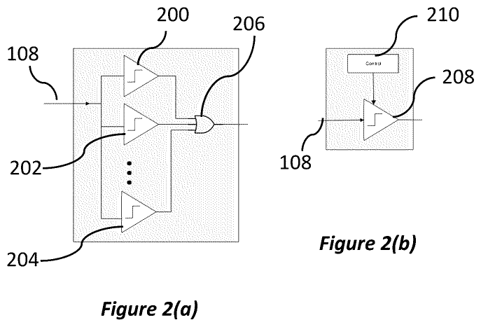

FIG. 2(a) is a schematic that is illustrative of the existing threshold checking techniques. The first signal 108 is received by a plurality of threshold checker circuits 200, 202, 204 each provides an output to a logic OR gate 206 that provides an output based the received signals. In this example, the threshold checkers 200, 202, 204 act concurrently to monitor the first signal 108.

FIG. 2(b) is a schematic that is illustrative of the threshold checking technique provided by the method 100. The first signal 108 is received by a threshold checker 208 which has its threshold value controller by a controller 210. Once the first threshold is crossed, as detected by the threshold checker 208, the controller changes the threshold value of the threshold checker 208 to the second threshold value. Therefore, in contrast with FIG. 2(b), only a single threshold checking operation is required thereby providing a more efficient threshold checking method.

In summary, FIGS. 2(a) and 2(b) show how N thresholds checkers could be optimized to one threshold checker and a control system.

This means rather than have N number of fixed-threshold checkers, a dynamic number can be used via the control block 210. It will be appreciated that although the illustration is for a rising signal, the same mathematical optimization can be done on falling signals by changing the signs or using a bidirectional detection checker. As such, there may be provided optimisation of multiple thresholds and conditions to one for rising and one for falling, or both rising and falling may be combined into a single threshold check.

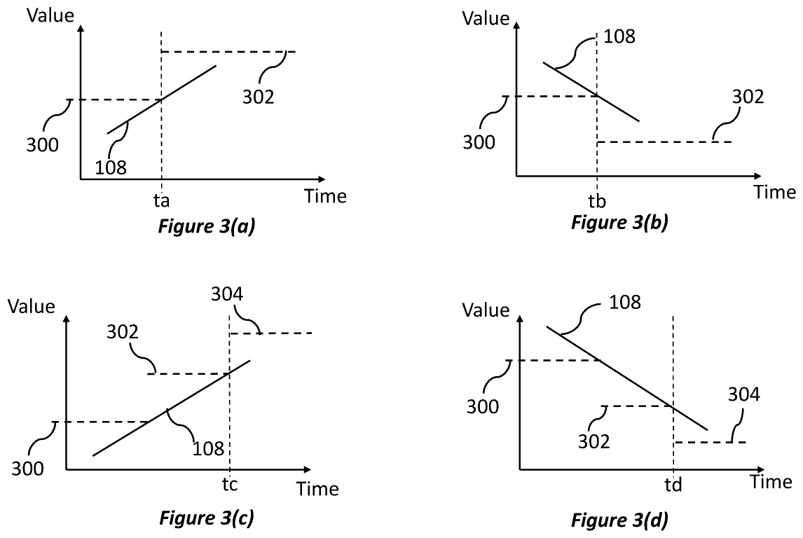

FIG. 3(a) is a graph showing the application of the method 100 in accordance with a second embodiment of the present disclosure. The y-axis denotes a value and in specific embodiments this value may, for example, denote a voltage, a current, a temperature or any other quantity to be monitored in the simulation, in accordance with the understanding of the skilled person. The x-axis denotes a time, and therefore the graph illustrates how the first signal 108 varies with time.

The following discussion relates to the first signal 108 traversing across a threshold, however it will be appreciated that in further embodiments, detection of the first signal and the generation of subsequent thresholds may relate to the first signal 108 reaching (in that it becomes approximately equal to) the relevant threshold value.

The first threshold value is denoted by reference numeral 300 and the second threshold value is denoted by a reference numeral 302. At a time ta, the first signal 108 traverses across the first threshold value 300, thereby resulting in the generation of the second threshold value 302. In the present example detecting that the first signal 108 has traversed across the first threshold value 300 comprises detecting that the first signal 108 has risen above the first threshold value 300, having been below the first threshold 300 value prior to the time ta. In the present example, generation of the second threshold value 304 is in response to the first signal 108 having risen above the first threshold value 300.

In a specific embodiment, the monitoring of the first signal 108 with respect to the first threshold value 300 may be halted after the first signal 108 has traversed across the first threshold value 300. By halting the threshold checking with respect to the first threshold value at this point, computation power can be reduced compared with ongoing monitoring with respect to the first threshold value.

However, it will be appreciated that in further embodiments it may be desirable to continue to monitor the first signal 108 with respect to the first threshold value 300 as is discussed below. This can lead to a reduction in CPU computation compared to known systems as only two threshold statement credentials need evaluating rather than 2 multiplied by N where N is an integer.

After generation of the second threshold value 302, the first signal 108 may be monitored with respect to the second threshold value 302.

FIG. 3(b) is a graph showing the application of the method 100 in accordance with a third embodiment of the present disclosure. The process shown by FIG. 3(b) may be understood with reference to the description of FIG. 3(a), however in the present example detecting of the first signal 108 having traversed across the first threshold value 300 comprises detecting that the first signal has fallen below the first threshold value 300 at a time tb. Generation of the second threshold value 302, in the present embodiment, is in response to the detection of the first signal 108 having fallen below the first threshold value 300.

FIG. 3(c) is a graph showing the application of the method 100 in accordance with a fourth embodiment of the present disclosure. The process shown by FIG. 3(c) may be understood with reference to the description of FIG. 3(a).

In the present example, the method 100 comprises detecting that the first signal 108 has traversed across the second threshold value 302.

In the present embodiment, detecting that the first signal 108 has traversed across the second threshold value 302 comprises detecting that the first signal 108 has risen above the second threshold value 302, as occurs at a time tc.

In the present embodiment, the method 100 comprises generating a third threshold value 304 in response to the detection of the first signal 108 having traversed across the second threshold value 302. Specifically, generation of the third threshold value 304 occurs when the first signal 108 has been detected as rising above the second threshold value 302.

FIG. 3(d) is a graph showing the application of the method 100 in accordance with a fifth embodiment of the present disclosure. The process shown by FIG. 3(d) may be understood with reference to the description of FIG. 3(c).

In the present example, the method 100 comprises detecting that the first signal 108 has traversed across the second threshold value 302 at a time td.

In the present embodiment, detecting that the first signal 108 has traversed across the second threshold value 302 comprises detecting that the first signal 108 has fallen below the second threshold value 302.

In the present embodiment, the method 100 comprises generating the third threshold value 304 in response to the detection of the first signal 108 having traversed across the second threshold value 302. Specifically, generation of the third threshold value 304 occurs when the first signal 108 has been detected as falling below the second threshold value 302.

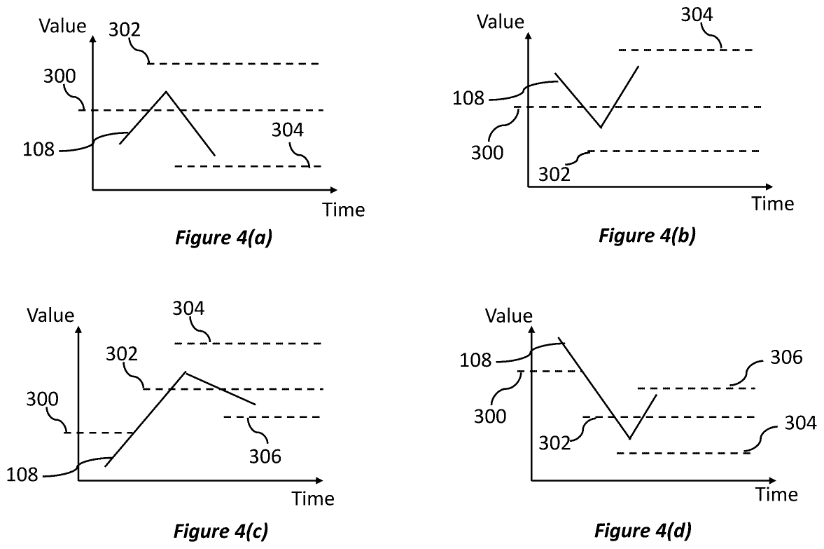

FIG. 4(a) is a graph showing the application of the method 100 in accordance with a sixth embodiment of the present disclosure. In the present embodiment, after having crossed the first threshold 300, the first signal 108 crosses the first threshold 300 in the opposite direction, thereby resulting in the generation of the third threshold 304. In the present example, the first signal 108 initially rises above the first threshold 300 before falling below the first threshold 300.

FIG. 4(b) is a graph showing the application of the method 100 in accordance with a seventh embodiment of the present disclosure. In the present embodiment, after having crossed the first threshold 300, the first signal 108 crosses the first threshold 300 in the opposite direction, thereby resulting in the generation of the third threshold 304. In the present example, the first signal 108 initially falls below the first threshold 300 before rising above the first threshold 300.

FIG. 4(c) is a graph showing the application of the method 100 in accordance with an eighth embodiment of the present disclosure, with a fourth threshold 306 being generated after the first signal 108 cross the second threshold 302 for a second time.

FIG. 4(d) is a graph showing the application of the method 100 in accordance with a ninth embodiment of the present disclosure, with the fourth threshold 306 being generated after the first signal 108 cross the second threshold 302 for a second time.

It will be appreciated that the application of the method 100 as described in relation to FIGS. 3(a)-3(d) and FIGS. 4(a)-4(d) can extend to any number of threshold values for a given application, and in accordance with the understanding of the skilled person.

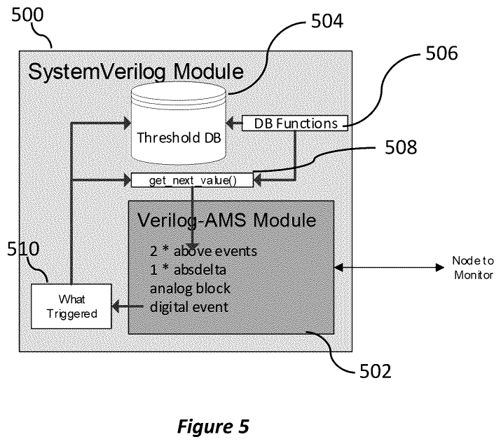

As discussed previously, the methods described herein may be applied using Verilog-AMS. FIG. 5 is a schematic of a SystemVerilog Module 500 which instances a Verilog-AMS Module 502. Using a SystemVerilog Module 500 that instances a Verilog-AMS Module 502 is established practice enabling features of SystemVerilog to interact with a Verilog-AMS module. FIG. 5 shows the general structure with the node to monitor.

This approach does not comprise true SystemVerilog-AMS but allows proposed dynamic threshold control to work. Generally, a SystemVerilog module is present so that digital event driven code can be used to control a Verilog-AMS module and, furthermore, the SystemVerilog module provides a richer language feature set compared with Verilog-AMS. The event driven code may be provided from the software-like UVM testbench wherein dynamic objects are standard practice.

The SystemVerilog Module 500 comprises a dynamic database (DB) construct 504 that is configured to store the details for each threshold that is to be monitored within the electronic circuit simulation, along with any other properties required by the simulation.

The dynamic element 504 can be populated by various methods in standard SystemVerilog code and is depicted as the ‘DB functions’ (having reference numeral 506). The DB functions 506 provides instructions to the DB construct 504 for adding, removing or updating threshold values.

For the “above” statement in the Verilog-AMS Module 502 the database properties to be stored in the DB construct 504, may include, but are not limited to: threshold; time tolerance; expression tolerance; direction; enable; and optionally a flag to indicate when the threshold has triggered.

The SystemVerilog Module 500 contains a routine called ‘get_next_value( )’ (denoted by reference numeral 508). get_next_value( ) may be used to calculate the next rising/falling above statement inputs to be set in the Verilog-AMS Module 502 and then passes them using Out-Of-Module-References (OOMR).

The “get_next_value( )” routine is called whenever there is a change to the DB 504 contents or a trigger is created in the Verilog-AMS 502 Module that requires the threshold values stored in the DB construct 504 to be recalculated. If the digital values to the “above” statements change values then the simulator classes this as a discharge to assess (D2A) event.

The “above” statements in the Verilog-AMS 502 generate an event in the digital domain which can be monitored via OOMR in the SystemVerilog Module 500. On triggering, a routine looks to see which of thresholds and properties would have triggered and sets the flag, shown as the ‘What Triggered’ box (denoted by reference numeral 510).

Additionally, the ‘get_next_value( )’ routine defines a value(s) above/below the current node value that is passed to the Verilog-AMS Module 502 to generate an event to cause the ‘get_next_value( )’ routine to be called. This is beneficial as the signal being monitored (the first signal, as discussed previously) may initially rise, so there is a new rising threshold setting, however, if the signal starts to fall, it could drop below a threshold in the DB 504 which means a new rising threshold is needed.

A similar system is beneficial in recalculating a rising threshold when the signal goes below the next highest thresholds below the currently measured value. This system can use the nearest analog timestep to further reduce CPU cycles as accuracy of the exact timestep and value may be reduced without degradation of performance.

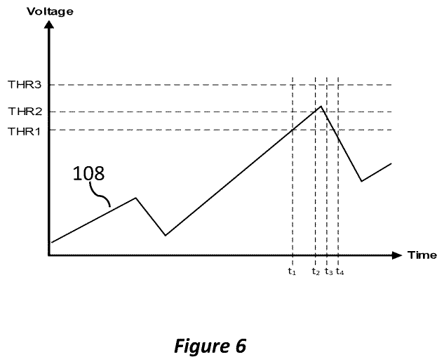

FIG. 6 is a graph showing the application of the method 100 and described in relation to the features of the SystemVerilog Module 500 as discussed previously, and in accordance with a tenth embodiment of the present disclosure.

The present example relates to a case where in addition to finding the next rising threshold to use, there is a process for recalculating the threshold if the signal 108 starts to fall instead of continuously rising.

In the present example, the “get_next_value( )” function looks at the next enabled rising threshold whose value is highest out of all the enabled rising thresholds but less than the current value on the node called, “rise_below_thresh”. This value is passed to the Verilog-AMS Module 502 via OOMR.

At the start of the simulation, the system performing the steps of the method 100, would set a first threshold value THR1 as the next above target settings. As there is no smaller threshold the “rise_below_thresh” system would be disabled by “rise_below_enable”.

When the first signal 108 crosses THR1 (at a time t1) it causes the “above” to generate an event. This calls “get_next_value( )” that will set a second threshold value THR2 as the next above threshold to use, but in addition set the first threshold value THR1 as the value for “rise_below_thresh”, such that if an analog time point is created below this value “get_next_value( )” is called.

When the first signal 108 goes above the second threshold THR2 (at a time t2) the “get_next_value( )” sets a third threshold value THR3 as the next threshold and the second threshold value THR2 as the one to retrigger “get_next_value( )”.

As the first signal 108 starts to fall it eventually falls below the second threshold THR2 at a time t3. At this point the system undertaking the steps of the method 100 sets the second threshold value THR2 as the next “above” setting and the first threshold value THR1 as a trigger point to call “get_next_value( )”.

The first signal 108 falls further where at the nearest simulation timepoint after a time t4, the system performing the steps of the method 100 will recalculate the setting making the first threshold TH1 the next “above” setting and disabling the system setting “rise_below_enable” by setting “rise_below_enable” equal to zero.

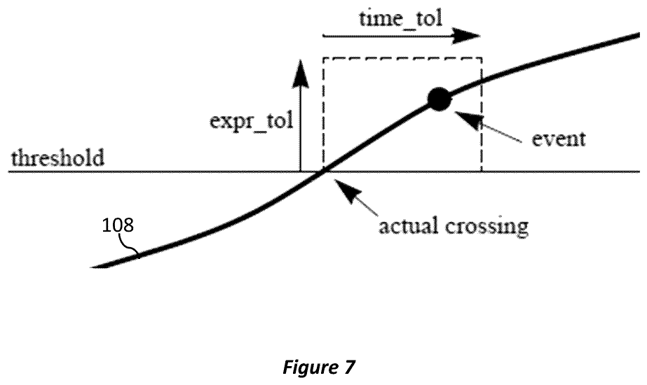

FIG. 7 is a graph showing the application of the method 100 and described in relation to the features of the SystemVerilog Module 500 as discussed previously, and in accordance with an eleventh embodiment of the present disclosure. In the present embodiment the syntax of the Verilog-AMS statement used as the statement for the threshold values is as follows:
above(expr[, time_tol[, exp_tol[, enable]]])

FIG. 7 shows how the inputs to the “above” statement bound the next analog simulation timestep and matrix solution point. expr_tol bounds the maximum distance past the threshold value that the analog value can be. This is used to control fast moving signals.

time_tol bounds how far in simulation time the analog timestep can be from the crossing point. This is used to control slow moving signals.

The two tolerances create a ‘bounding box’ with the origin being the threshold point expr. expr can be an expression and it is when this expression goes above 0 the function must create an analog time step bound by expr_tol and time_tol. To provide a threshold other than 0 then expr input can be written as such V(node)-Vth, where with sets the threshold point.

Specifying a small time_tol can ensure that a slowly-varying expression triggers an event within a reasonable time from the actual crossing point, and specifying a small exp_tol can ensure that a rapidly-varying expression triggers an event within a reasonable value of the actual crossing point. However, setting either of these tolerances to unreasonably small values can adversely affect the simulator's performance. If a tolerance is not specified, then the tool (e.g., the simulator) may automatically set it.

In summary, the “above” and “cross” statements of Verilog-AMS include a threshold (expr), threshold tolerance (expr_tol) and time tolerance (ttol) to form what is referred to as a bounding box to the analog solver ensuring a timestep and value is create inside the box when the signal goes above the threshold. This sort of bound box is likely to be present in future versions as an analog solver preferably has the freedom to choose a data point within tolerances of the desired point.

SystemVerilog has various ways to define data structures and store the data dynamically as it has object-oriented language features as well as a hardware description capability. For example, somewhere in the test environment a request for a new threshold may be made, where a new identifier for a new threshold element in the dynamic data storage is returned and this is then used for all future operations on this threshold setting. There may be a unique number for this request, where a new setting is applied using the unique identifier. When there is a change to the data store, the function ‘get_next_value( )’ may be called to work out the setting for the “above statements” in the Verilog-AMS Module 502.

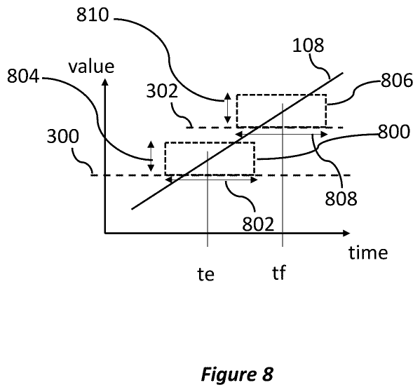

FIG. 8 is a graph showing a specific implementation of an application of the method 100 where detection of the first signal 108 in relation to threshold values uses bounding boxes as discussed previously, and in accordance with twelfth embodiment of the present disclosure.

The method 100 comprises monitoring the first signal 108 with respect to the first threshold value 300 and the second threshold value 302 over a sequence of time steps te, tf.

Detecting that the first signal 108 has traversed across the first threshold value 300 comprises detecting that the first signal 108 is within a first bounding box 800 of the first threshold value 108. The first bounding box 800 is dependent on a first time step te, a first time tolerance 802 and a first threshold tolerance 804.

Detecting that the first signal 108 has traversed across the second threshold value 302 may comprise detecting that the first signal 108 is within a second bounding box 806 of the second threshold value 302. The second bounding box 806 is dependent on a second time step tf, a second time tolerance 808 and a second threshold tolerance 810.

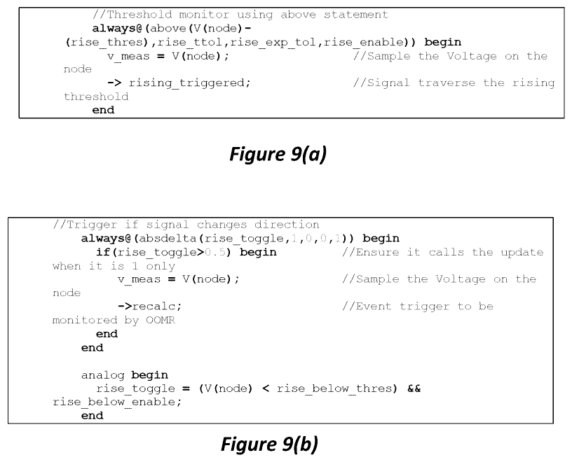

FIG. 9(a) is an illustration of example code that may be used in a specific embodiment of the present disclosure. The code shown in FIG. 9(a) may be used to monitor the threshold of the signal (rising in this case), for example, as may be applicable in FIGS. 3(a)-(d), in accordance with the understanding of the skilled person.

FIG. 9(b) is an illustration of example code that may be used in a further specific embodiment of the present disclosure. In the present embodiment rise_below_thresh/rise_below_enable are used to generate the rise_toggle signal. The example code presented in FIG. 9(b) may be used to detect if the signal was rising above then falling below the last threshold, for example, as may be applicable in FIGS. 4(a)-(d), in accordance with the understanding of the skilled person.

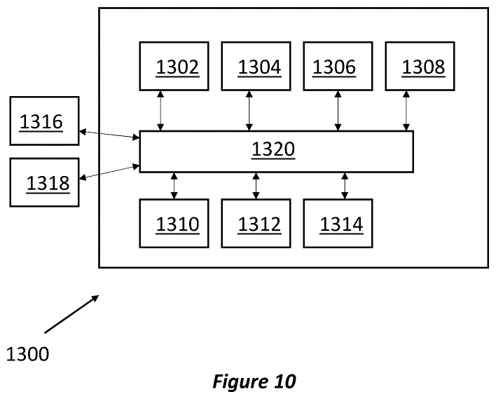

FIG. 10 is a schematic of a computer system 1300 which comprises specially modified components for carrying out the methods of the present disclosure, and in accordance with a thirteenth embodiment of the present disclosure. The computer system 1300 comprises a module 1302 which is configured as an electronic circuit simulation tool that has a function to enable the monitoring of a first signal with respect to a plurality of threshold values within a simulation performed by the electronic circuit simulation tool. The method 100, and the specific embodiments of the method 100 as described herein may be run using the electronic circuit simulation tool.

The computer system 1302 may comprise a process 1304, a storage device 1306, RAM 1308, ROM 1310, a data interface 1312, a communications interface 1314, a display 1316, and an input device 818. The computer system 1300 may comprise a bus 1320 to enable communication between the different components.

The computer system may be configured to load an application. The instructions provided by the application may be carried out by the process 1304. The application may be the electronic circuit simulation tool.

A user may interact with the computer system 1300 using the display 1316 and the input device 1318 to instruct the computer system 1300 to implement the methods of the present disclosure in the monitoring of a first signal within an electronic circuit simulation environment.

The methods disclosed herein may be used ensure that each threshold detection is independent of all others, and to ensure than no threshold is missed. Furthermore, the methods disclosed herein may use industry standard languages or interfaces, such as Verilog-AMS and SystemVerilog.

Furthermore, embodiments of the methods disclosed herein can provide a dynamic system that can reduce the number of threshold checkers using at least one of the following:
Variable thresholds/bounding box checks
A minimal number of signal element threshold checkers.
A dynamic API system which determines the signal element type and the implementation of the check.

Furthermore, embodiments of the methods disclosed herein can be used to detect possible oscillation issues if the rising and/or falling thresholds are too close to each other.

Various improvements and modifications may be made to the above without departing from the scope of the disclosure.

1. A computer-implemented method of monitoring a first signal with respect to a plurality of threshold values within a simulation of an electronic circuit, the method comprising:
providing a first threshold value;
monitoring the first signal with respect to the first threshold value;
detecting that the first signal has reached or has traversed across the first threshold value; and
generating a second threshold value in response to the detection of the first signal having reached or having traversed across the first threshold value.

2. The method of claim 1, wherein the first signal comprises an analog signal or a digital signal.

3. The method of claim 1, wherein the simulation of the electronic circuit is undertaken using a hardware description language.

4. The method of claim 1, wherein the hardware description language is SystemVerilog.

5. The method of claim 4, wherein the hardware description language is Verilog-AMS.

6. The method of claim 1 comprising:
stopping the monitoring of the first signal with respect to the first threshold value after detecting that the first signal has reached or has traversed across the first threshold value.

7. The method of claim 1, wherein detecting that the first signal has traversed across the first threshold value comprises:
detecting that the first signal has risen above the first threshold value; or
detecting that the first signal has fallen below the first threshold value.

8. The method of claim 7, wherein generating a second threshold value in response to the detection of the first signal having traversed across the first threshold value comprises:
generating a second threshold value in response to the detection of the first signal having risen above the first threshold value; or
generating a second threshold value in response to the detection of the first signal having fallen below the first threshold value.

9. The method of claim 1, wherein generating a second threshold value comprises: accessing a memory element that is configured to store one or more stored threshold values;
extracting a stored threshold value from the memory element; and
setting the extracted stored threshold value as the second threshold value.

10. The method of claim 9, comprising storing one or more stored threshold values within the memory element during the running of the simulation and prior to the generation of the second threshold value.

11. The method of claim 1 comprising monitoring the first signal with respect to the second threshold value.

12. The method of claim 11 comprising detecting that the first signal has reached or has traversed across the second threshold value.

13. The method of claim 12, wherein detecting that the first signal has traversed across the second threshold value comprises:
detecting that the first signal has risen above the second threshold value; or
detecting that the first signal has fallen below the second threshold value.

14. The method of claim 12 comprising generating a third threshold value in response to the detection of the first signal having reached or having traversed across the second threshold value.

15. The method of claim 14, wherein generating a third threshold value in response to the detection of the first signal having traversed across the second threshold value comprises:
generating a third threshold value in response to the detection of the first signal having risen above the second threshold value; or
generating a third threshold value in response to the detection of the first signal having fallen below the second threshold value.

16. The method of claim 15 comprising detecting that the first signal has reached or has traversed across the first threshold value for a second time, and generating a fourth threshold value in response to the detection of the first signal having reached or having traversed across the first threshold value a second time.

17. The method of claim 12, comprising monitoring the first signal with respect to the first threshold value and the second threshold value over a sequence of time steps.

18. The method of claim 17, wherein detecting that the first signal has traversed across the first threshold value comprises detecting that the first signal is within a first bounding box of the first threshold value, the first bounding box being dependent on a first time step, a first time tolerance and a first threshold tolerance.

19. The method of claim 18, wherein detecting that the first signal has traversed across the second threshold value comprises detecting that the first signal is within a second bounding box of the second threshold value, the second bounding box being dependent on a second time step, a second time tolerance and a second threshold tolerance.

20. A electronic circuit simulation tool configured to monitor a first signal with respect to a plurality of threshold values within a simulation performed by the electronic circuit simulation tool, the electronic circuit simulation tool being configured to:
provide a first threshold value;
monitor the first signal with respect to the first threshold value;
detect that the first signal has reached or has traversed across the first threshold value; and
generate a second threshold value in response to the detection of the first signal having reached or having traversed across the first threshold value.
